(19) United States
(12) Patent Application Publication
(10) Pub. No.: US 2021/0210568 A1
(43) Pub. Date: Jul. 8, 2021

(54) SUBSTRATE, DISPLAY PANEL AND DISPLAY DEVICE

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Xiaoxia HUANG, Beijing (CN); Bing JI, Beijing (CN); Jie ZENG, Beijing (CN); Binfeng FENG, Beijing (CN)

(21) Appl. No.: 16/760,054

(22) PCT Filed: Sep. 17, 2019
(86) PCT No.: PCT/CN2019/106097

§ 371 Date: Apr. 29, 2020

(30) Foreign Application Priority Data
Sep. 21, 2018 (CN) 201811110553.7

(51) Int. Cl. H01L 27/32; G06K 9/00; G02F 1/1368; H01L 51/52

(52) U.S. Cl. CPC H01L 27/3234; G06K 9/0004; H01L 51/529; G02F 1/1368; H01L 27/3244; G06K 9/0002

(57) ABSTRACT

A substrate is provided, including a base substrate; a film layer on the base substrate, the film layer including an opening; a fingerprint identification circuit located in the opening; and a connection line connected with the fingerprint identification circuit, the connection line being at least partly embedded in the film layer. A display panel and a display device including the substrate are also provided.

### RELATED APPLICATIONS

The present application is a 35 U.S.C. 371 national stage application of a PCT International Application No. PCT/CN2019/106097, filed on Sep. 17, 2019, which claims the benefits of priority of Chinese patent application No. 201811110553.7 filed on Sep. 21, 2018, the entire disclosure of which is incorporated herein by reference.

### TECHNICAL FIELD

This disclosure relates to the field of display technologies, and in particular to a substrate, a display panel and a display device.

### BACKGROUND

With rapid development of science and technology, various terminal devices have become necessities in our life, and users' requirements for the terminal devices are getting higher and higher. In terms of security, fingerprints identification has widely applied in various terminal devices due to their individual uniqueness in order to enhance user's experience and security.

### SUMMARY

In an aspect, a substrate is provided, comprising: a base substrate; a film layer on the base substrate, the film layer comprising an opening; a fingerprint identification circuit in the opening, and a connection line connected with the fingerprint identification circuit, the connection line being at least partly embedded in the film layer.

According to some embodiments of the disclosure, the film layer comprises a plurality of sub-layers, and the connection line is located in one of the plurality of sub-layers.

According to some embodiments of the disclosure, the film layer comprises a plurality of sub-layers, and the connection line is located between two adjacent sub-layers of the plurality of sub-layers.

According to some embodiments of the disclosure, the film layer comprises a heat dissipation film.

According to some embodiments of the disclosure, the heat dissipation film comprises a glue layer, a buffer layer, a metal layer and a release film stacked on the base substrate sequentially.

According to some embodiments of the disclosure, the connection line is located in the buffer layer.

According to some embodiments of the disclosure, the connection line is located between the buffer layer and the metal layer.

According to some embodiments of the disclosure, the connection line is connected with the fingerprint identification circuit at two positions of the fingerprint identification circuit symmetrical with respect to a central line of the fingerprint identification circuit.

According to some embodiments of the disclosure, an orthogonal projection of the fingerprint identification circuit on the base substrate is rectangular, and the connection line is connected with the fingerprint identification circuit on at least three side surfaces of the fingerprint identification circuit.

According to some embodiments of the disclosure, a distance between the position where the connection line is connected with the fingerprint identification circuit and the position where the connection line extends into the film layer is equal to a distance from a center point of the fingerprint identification circuit to a side wall of the opening.

According to some embodiments of the disclosure, an orthogonal projection of the opening on the base substrate is rectangular, and the fingerprint identification circuit is located at the center of the opening.

In another aspect, a display panel is proposed, which comprises the substrate according to any one of the foregoing embodiments.

According to some embodiments of the disclosure, the display panel is a liquid crystal display panel, and the substrate is an array substrate of the liquid crystal display panel, and the liquid crystal display panel comprises a thin film transistor on a surface of the base substrate facing the film layer and the fingerprint identification circuit.

According to some embodiments of the disclosure, the display panel is an electroluminescent display panel, and the substrate is an OLED substrate or a QLED substrate of the electroluminescent display panel, and the electroluminescent display panel comprises a thin film transistor, a first electrode, a light-emitting functional layer and a second electrode on a surface of the base substrate facing the film layer and the fingerprint identification circuit.

In yet another aspect, a display device comprising the display panel according to any one of the foregoing embodiments is proposed.

According to some embodiments of the disclosure, the display device further comprises a motherboard, the connection line is connected with the motherboard, and the motherboard is configured to receive a signal transmitted by the connection line to achieve fingerprint identification.

According to some embodiments of the disclosure, the motherboard is connected with the connection line via a main control line.

### BRIEF DESCRIPTION OF DRAWINGS

In order to explain the technical solutions in the embodiments of this disclosure more clearly, the drawings to be mentioned in the description of the embodiments will be introduced briefly below. Apparently, the drawings described below are only some embodiments of this disclosure, and for one having ordinary skills in the art, other drawings can also be obtained from these drawings without inventive efforts.

FIG. 1 is a schematic view of a typical display device;

FIG. 2 is a schematic view of a substrate provided in an embodiment of this disclosure;

FIG. 3(A) illustrates a film layer in a substrate provided in an embodiment of this disclosure;

FIG. 3(B) illustrates a film layer in a substrate provided in another embodiment of this disclosure;

FIG. 4(A) is a schematic view showing a connection line being connected with a fingerprint module provided in an embodiment of this disclosure;

FIG. 4(B) is a schematic view showing a connection line being connected with a fingerprint module provided in another embodiment of this disclosure;

FIG. 5 is a schematic view showing a connection line being connected with a fingerprint module provided in another embodiment of this disclosure; and

FIG. 6 is a schematic view of a display device provided in an embodiment of this disclosure.

### DETAILED DESCRIPTION OF EMBODIMENTS

The technical solutions in the embodiments of this disclosure will be described clearly and completely below with reference to the drawings of this disclosure. Apparently, the described embodiments are only part of the possible embodiments of this disclosure, rather than all of them. Based on the embodiments in this disclosure, other embodiments obtainable by one having ordinary skills in the art without inventive efforts shall all fall within the protection scope of this disclosure.

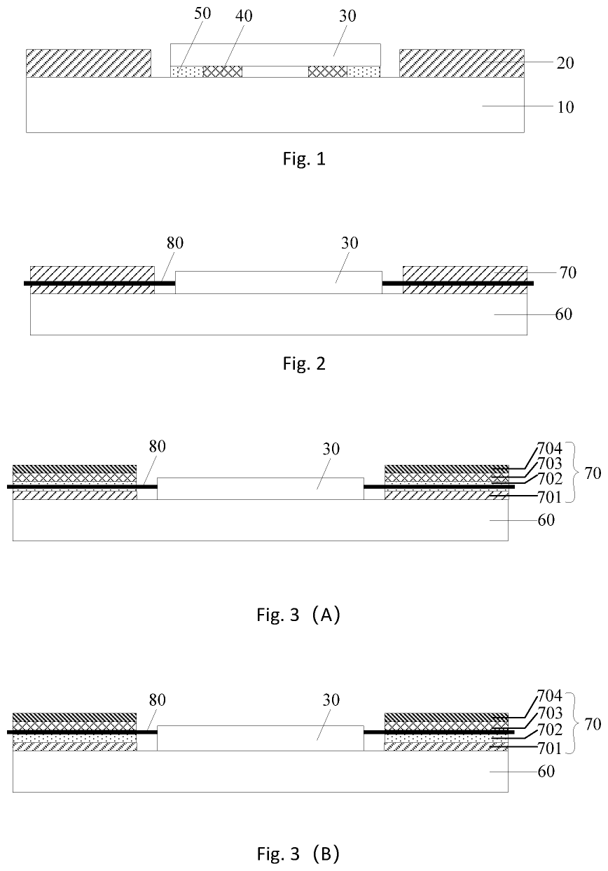

For a full screen display device, the fingerprint identification circuit is usually attached to the back of the display panel. As shown in FIG. 1, a display panel 10 is provided with a heat dissipation film 20 attached to its back. The heat dissipation film 20 has an opening. A fingerprint identification circuit 30 is arranged in the opening of the heat dissipation film 20, and the fingerprint identification circuit 30 and the display panel 10 are assembled together using a frame sealant 40 and an edge sealant 50. However, in such a configuration, since the frame sealant 40 and the edge sealant 50 which considerably differ from the display panel 10 in characteristics such as thermal expansion coefficient, are only arranged in the opening of the heat dissipation film 20, indentations may be easily caused at the positions of the display panel 10 corresponding to the fingerprint identification circuit 30, which results in unevenness of the display panel 10 and thus affects the display effect.

In view of this, the embodiments of this disclosure provide a substrate, as shown in FIG. 2, comprising a base substrate 60 and a film layer 70 on the base substrate 60, and the film layer 70 comprises an opening. The substrate further comprises a fingerprint identification circuit 30 located in the opening of the film layer 70. A connection line 80 connected with the fingerprint identification circuit 30 is at least partly located in the film layer 70.

Herein, the type of the film layer 70 on the base substrate 60 is not limited, and it can be any film layer arranged upon functions to be achieved. For example, the film layer 70 may be a protection film configured to protect the substrate, or a heat dissipation film configured to dissipate heat, and so on.

Based on that, the film layer 70 may comprise one or more sub-layers. When the film layer 70 comprises a plurality of sub-layers, the connection line 80 connected with the fingerprint identification circuit 30 may be located in any sub-layer of the film layer 70, or between two adjacent sub-layers of the film layer 70.

Herein, the shape and the size of the opening of the film layer 70 are not limited, as long as the fingerprint identification circuit 30 can be arranged in the opening of the film layer 70. Besides, the position of the opening in the film layer 70 may be positioned in accordance with the position of the fingerprint identification circuit 30 on the base substrate 60, and the position of the fingerprint identification circuit 30 on the base substrate 60 may be determined correspondingly as required by the user.

The connection line 80 connected with the fingerprint identification circuit 30 may be a rigid or flexible electrical connection structure, such as a flexible printed circuit (FPC), a flexible flat cable (FFC), or a printed circuit board (PCB), and so on.

Herein, the details of the fingerprint identification circuit 30 are not limited, as long as a fingerprint identification function can be achieved. For example, the fingerprint identification circuit 30 may be either a capacitive fingerprint identification module, or an optical fingerprint identification module. Specifically, the capacitive fingerprint identification module may comprise a drive electrode and a sense electrode or the like, and the optical fingerprint identification module may comprise a light source, a prism, an image sensor and so on.

For the above substrate provided in the embodiments of this disclosure, since the connection line 80 connected with the fingerprint identification circuit 30 is located in the film layer 70, the fingerprint identification circuit 30 can be fixed in the opening of the film layer 70. Furthermore, since the film layer 70 is fixed on the base substrate 60, the fingerprint identification circuit 30 can be brought into close contact with the base substrate 60. As compared with the solution of FIG. 1 in which the fingerprint identification circuit 30 is attached to the base substrate 60 by means of the frame sealant 40 and the edge sealant 50, when the substrate provided in this embodiment is applied to the display panel 10, the frame sealant 40 or edge sealant 50 is not necessary, thereby avoiding the problem of impaired display effect resulting from indentations caused at the positions of the display panel 10 corresponding to the fingerprint identification circuit 30 due to the frame sealant 40 and the edge sealant 50.

Further, for the solution of FIG. 1, the connection line connected with the fingerprint identification circuit 30 is usually arranged above the film layer 70. Since further structures such as a motherboard or a control line may be arranged above the film layer 70, in order to avoid mutual influence between the further structures and the connection line, the further structures usually need to bypass the connection line, which increases the difficulties of designing and manufacture process of the substrate. In contrast, with the above embodiments of this disclosure, the connection line 80 is located in the film layer 70, which avoids the problem of increased difficulties of design and process due to that the connection line 80 is located above the film layer 70.

In an embodiment, the film layer 70 comprises a heat dissipation film. As used herein, the term “heat dissipation film” refers to any film layer having a heat dissipation function, which can be a single layered or multi-layered structure, and can have functions other than heat dissipation upon needs. By arranging a heat dissipation film on the display panel, the temperature of the display panel can be lowered and the problem of a heated display panel can be alleviated. The structure of the heat dissipation film is not limited, and the heat dissipation film can comprise either a single layer, or multiple sub-layers, so as to implement different functions.

When the heat dissipation film comprises a plurality of sub-layers, as an example, the connection line 80 may be located in any sub-layer. Alternatively, the connection line 80 may be located between any two adjacent sub-layers.

In an embodiment, as shown in FIG. 3(A), the heat dissipation film comprises a glue layer 701, a buffer layer 702, a metal layer 703 and a release film 704, and the connection line 80 is located in the buffer layer 702. In an alternative embodiment, as shown in FIG. 3(B), the connection line 80 is located between the buffer layer 702 and the metal layer 703. When the connection line 80 is located between the buffer layer 702 and the metal layer 703, during the manufacture, the buffer layer 702 may be manufactured firstly, and then the connection line 80 is fabricated on the buffer layer 702 and the metal layer 703 may be fabricated on the connection line 80. In this case, the connection line 80 may be a connection structure comprising an insulating encapsulation layer.

In the above embodiments of this disclosure, by arranging the connection line 80 between two adjacent sub-layers of the heat dissipation film, on one hand, the connection line 80 can be firmly fixed in the heat dissipation film, and on the other hand, any sub-layer of the heat dissipation film can be manufactured at one time, which improves the efficiency of the manufacture of the heat dissipation film.

In the embodiment of this disclosure, when the heat dissipation film comprises multiple sub-layers, the heat dissipation film can have a structure as shown in FIG. 3(A) and FIG. 3(B), comprising a glue layer 701, a buffer layer 702, a metal layer 703 and a release film 704 sequentially stacked on the base substrate 60. When the connection line 80 is located in any sub-layer of the heat dissipation film, e.g., as shown in FIG. 3(A), the connection line 80 is located in the buffer layer 702.

Specifically, the glue layer 701 is configured to fix the heat dissipation film closely on the base substrate 60. The glue layer 701 can be made from embossing (EMBO). The material of the buffer layer 702 is not limited, e.g., it may comprise foam or the like. The material of the metal layer 703 is not limited, e.g., it can be at least one of single metals such as copper (Cu), molybdenum (Mo) and aluminum (Al), or alloys thereof.

For the above embodiments of this disclosure, when the heat dissipation film comprises a glue layer 701, a buffer layer 702, a metal layer 703 and a release film 704 sequentially stacked on the base substrate 60, the heat dissipation film can achieve a good heat dissipation effect.

In the embodiment shown in FIG. 2, if the connection line 80 is only connected with one side of the fingerprint identification circuit 30, although the fingerprint identification circuit 30 can be fixed in the opening of the film layer 70, the other side of the fingerprint identification circuit 30 may be warped such that the fingerprint identification circuit 30 is not in contact with the base substrate 60 fully or completely.

Based on that, as an example, as shown in FIG. 2, FIG. 3(A) and FIG. 3(B), the connection line 80 is connected with the fingerprint identification circuit 30 at two positions of the fingerprint identification circuit 30 symmetrical with respect to a central line of the fingerprint identification circuit 30. As used herein, the term “central line” refers to a line passing through the center of the fingerprint identification circuit 30 and extending in a direction perpendicular to the base substrate 60.

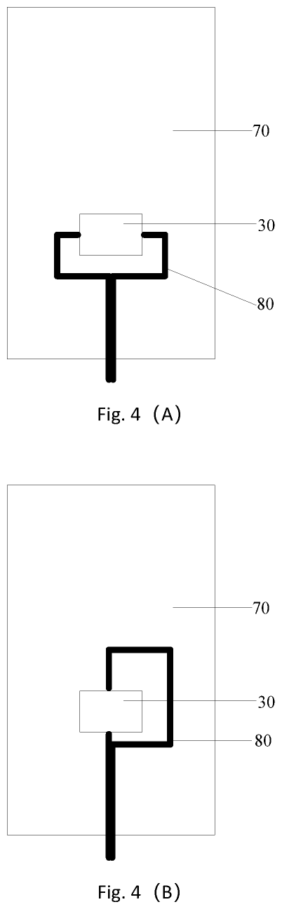

The two positions of the fingerprint identification circuit 30 symmetrical with respect to the central line of the fingerprint identification circuit 30 can be selected at will based on the shape of the fingerprint identification circuit 30. For example, if an orthogonal projection of the fingerprint identification circuit 30 on the base substrate 60 is rectangular, and as shown in the top view of FIG. 4(A), the two positions symmetrical with respect to the central line of the fingerprint identification circuit 30 can be located on the left side and the right side of the fingerprint identification circuit 30 respectively, i.e., the connection line 80 is connected with the fingerprint identification circuit 30 on the left side and the right side of the fingerprint identification circuit 30. Alternatively, as shown in FIG. 4(B), the two positions symmetrical with respect to the central line of the fingerprint identification circuit 30 may be located on the upper side and the lower side of the fingerprint identification circuit 30 respectively, i.e., the connection line 80 is connected with the fingerprint identification circuit 30 on the upper side and the lower side of the fingerprint identification circuit 30.

In the above embodiments of this disclosure, since the connection line 80 is connected with the fingerprint identification circuit 30 at least at two positions of the fingerprint identification circuit 30 symmetrical with respect to the central line of the fingerprint identification circuit 30, not only can the fingerprint identification circuit 30 be fixed in the opening of the film layer 70, but also the surface of the fingerprint identification circuit 30 facing the base substrate 60 can be brought into close contact with the base substrate 60 fully and completely.

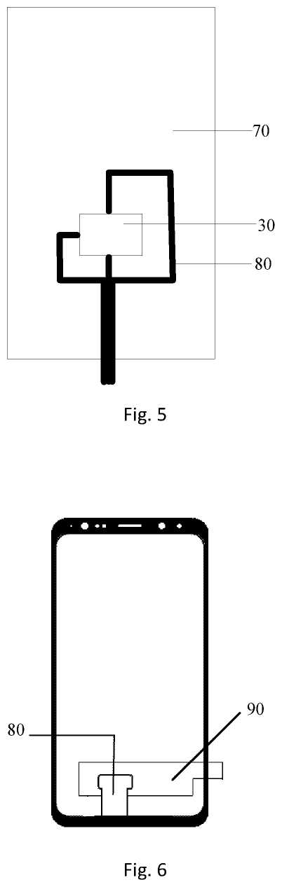

In case the orthogonal projection of the fingerprint identification circuit 30 on the base substrate 60 is rectangular, as an example, as shown in FIG. 5, the connection line 80 is connected with the fingerprint identification circuit 30 on at least three sides of the fingerprint identification circuit 30.

As used herein, the surface of the fingerprint identification circuit 30 facing the base substrate 60 is referred to as a bottom surface, and the surface opposite to the bottom surface of the fingerprint identification circuit 30 is referred to as a top surface, and the other surfaces of the fingerprint identification circuit 30 are referred to as side surfaces.

It should be noted that the fingerprint identification circuit 30 can be connected with one, two or more connection lines 80 at any side surface of the fingerprint identification circuit 30.

In an embodiment of this disclosure, in case the orthogonal projection of the fingerprint identification circuit 30 on the base substrate 60 is rectangular, the connection line 80 may be connected with the fingerprint identification circuit 30 on at least three side surfaces of the fingerprint identification circuit 30, which can further ensure that the fingerprint identification circuit 30 is fixed in the opening of the film layer 70 and that the surface of the fingerprint identification circuit 30 facing the base substrate 60 is in close contact with the base substrate 60 fully and completely.

In practice, if a distance between the position where the connection line 80 is connected with the fingerprint identification circuit 30 and the position where the connection line 80 extends into the film layer 70 is greater than a distance from a center point of the fingerprint identification circuit 30 to a side wall of the opening of the film layer 70, the fingerprint identification circuit 30 may wobble in the opening of the film layer 70. In view of this, as an example, the distance between the position where the connection line 80 is connected with the fingerprint identification circuit 30 and the position where the connection line 80 extends into the film layer 70 may be equal to the distance from the center point of the fingerprint identification circuit 30 to the side wall of the opening of the film layer 70.

In the above embodiments of this disclosure, since the distance between the position where the connection line 80 is connected with the fingerprint identification circuit 30 and the position where the connection line 80 extends into the film layer 70 is equal to the distance from the center point of the fingerprint identification circuit 30 to the side wall of the opening of the film layer 70, the fingerprint identification circuit 30 can be prevented from wobbling in the opening of the film layer 70.

Optionally, if the orthogonal projection of the fingerprint identification circuit 30 on the base substrate 60 is generally rectangular, in order that the fingerprint identification circuit 30 can be arranged in the opening of the film layer 70, the opening in the film layer 70 is a rectangular opening, which is easier to make than openings in other shapes. Further, the fingerprint identification circuit 30 may be located at the center of the rectangular opening, i.e., the distances from any two opposite side surfaces of the fingerprint identification circuit 30 to the edge of the opening are equal so as to prevent the fingerprint identification circuit 30 from wobbling in the opening.

Another embodiment of the disclosure further provides a display panel, comprising the substrate according to any of the above embodiments.

The display panel provided in the embodiments of this disclosure can be either a liquid crystal display panel (LCD), or an electroluminescent display panel. Here, the electroluminescent display panel can be either an organic light emitting display (OLED) panel, or a quantum dot light-emitting display (QLED) panel.

It should be noted that when the display panel is a liquid crystal display panel, it typically comprises an array substrate, a color filter substrate and a liquid crystal layer between the array substrate and the color filter substrate. In this case, the substrate described in the above embodiment may be an array substrate of the liquid crystal display panel. When the substrate provided above is an array substrate, the array substrate further comprises thin film transistors located on the base substrate. The thin film transistors are located on a surface of the base substrate 60 facing the film layer 70 and the fingerprint identification circuit 30.

When the display panel is an electroluminescent display panel, it typically comprises an OLED substrate (or a QLED substrate) and an encapsulation cover plate or an encapsulation film layer for encapsulating the OLED substrate (or the QLED substrate). In this case, the substrate provided above can be an OLED substrate or a QLED substrate. When the substrate provided above is an OLED substrate or a QLED substrate, it further comprises a thin film transistor, a first electrode, a light-emitting functional layer, a second electrode and so on located on the base substrate 60. The thin film transistor, the first electrode, the light-emitting functional layer and the second electrode are located on a surface of the base substrate 60 facing the film layer 70 and the fingerprint identification circuit 30.

For the above display panel provided in the embodiments of this disclosure, the substrate in the display panel has the same structure and beneficial effects as the substrate provided in the foregoing embodiments, and since the structure and the beneficial effects of the substrate have been described in detail above, they will not be repeated herein for simplicity.

The embodiments of this disclosure further provide a display device, comprising the display panel according to any of the above embodiments.

The display device can be any device that displays an image, no matter whether the image is moving (e.g., a video) or stationary (e.g., a still image), or whether it is a text or a drawing. More specifically, it is contemplated that the embodiments may be implemented in or associated with a variety of electronic devices such as, but not limited to, mobile phones, wireless devices, personal data assistants (PDAs), hand-held or portable computers, GPS receivers/navigators, cameras, MP4 video players, camcorders, game consoles, wrist watches, clocks, calculators, television monitors, flat panel displays, computer monitors, auto displays (e.g., odometer display, etc.), navigators, cockpit controls and/or displays, displays of camera views (e.g., display of a rear view camera in a vehicle), electronic photographs, electronic billboards or signs, projectors, architectural structures, packaging and aesthetic structures (e.g., display of images on a piece of jewelry).

For the display device provided in the embodiments herein, the display panel comprises the above substrate, so the display device has the same structure and beneficial effects as the substrate provided in the foregoing embodiments, and since the structure and the beneficial effects of the substrate have been described in detail above, they will not be repeated herein for simplicity.

In an embodiment, the display device further comprises a motherboard, and the connection line 80 is further connected with the motherboard. Alternatively, as shown in FIG. 6, the display device further comprises a motherboard and a main control line 90, and the connection line 80 is connected with the motherboard via the main control line 90. In particular, the motherboard is configured to receive signals transmitted by the connection line 80 so as to achieve fingerprint identification.

FIG. 6 schematically shows a display device which is a cell phone for example, and FIG. 6 only schematically shows the connection line 80 and the main control line 90, instead of the motherboard and other structures.

In an embodiment of this disclosure, the connection line 80 connected with the fingerprint identification circuit 30 are located in the film layer 70 and extend beyond the edge of the film layer 70, such that connectors are exposed on the edge of the film layer 70, which are folded back to a surface of the film layer 70, and then plugged in or bound with the motherboard or the main control line 90.

In the above embodiments of this disclosure, since the connection line 80 is connected with the fingerprint identification circuit 30, and the connection line 80 is also connected with the motherboard directly or via the main control line 90, the fingerprint identification circuit 30 can be connected with the motherboard, and the motherboard can receive the signals transmitted by the connection line 80, thereby achieving the function of fingerprint identification.

What is discussed above is only specific embodiments of this disclosure, but the protection scope of this disclosure shall not be limited thereto. Any variation or substitution easily conceivable within the technical disclosure of this disclosure for one skilled person who is familiar with this art shall fall within the protection scope of this disclosure. Therefore, the protection scope of this disclosure should be subject to the protection scope of the appended claims.

1. A substrate, comprising:
a base substrate;
a film layer on the base substrate, the film layer comprising an opening;
a fingerprint identification circuit in the opening, and
a connection line connected with the fingerprint identification circuit, the connection line being at least partly embedded in the film layer.

2. The substrate according to claim 1, wherein the film layer comprises a plurality of sub-layers, and the connection line is located in one of the plurality of sub-layers.

3. The substrate according to claim 1, wherein the film layer comprises a plurality of sub-layers, and the connection line is located between two adjacent sub-layers of the plurality of sub-layers.

4. The substrate according to claim 1, wherein the film layer comprises a heat dissipation film.

5. The substrate according to claim 4, wherein the heat dissipation film comprises a glue layer, a buffer layer, a metal layer and a release film stacked on the base substrate sequentially.

6. The substrate according to claim 5, wherein the connection line is located in the buffer layer.

7. The substrate according to claim 5, wherein the connection line is located between the buffer layer and the metal layer.

8. The substrate according to claim 1, wherein the connection line is connected with the fingerprint identification circuit at two positions of the fingerprint identification circuit symmetrical with respect to a central line of the fingerprint identification circuit.

9. The substrate according to claim 8, wherein an orthogonal projection of the fingerprint identification circuit on the base substrate is rectangular, and the connection line is connected with the fingerprint identification circuit on at least three side surfaces of the fingerprint identification circuit.

10. The substrate according to claim 1, wherein a distance between the position where the connection line is connected with the fingerprint identification circuit and the position where the connection line extends into the film layer is equal to a distance from a center point of the fingerprint identification circuit to a side wall of the opening.

11. The substrate according to claim 9, wherein an orthogonal projection of the opening on the base substrate is rectangular, and the fingerprint identification circuit is located at the center of the opening.

12. A display panel, comprising the substrate according to claim 1.

13. The display panel according to claim 12, wherein the display panel is a liquid crystal display panel, and the substrate is an array substrate of the liquid crystal display panel, and the liquid crystal display panel comprises a thin film transistor on a surface of the base substrate facing the film layer and the fingerprint identification circuit.

14. The display panel according to claim 12, wherein the display panel is an electroluminescent display panel, and the substrate is an OLED substrate or a QLED substrate of the electroluminescent display panel, and the electroluminescent display panel comprises a thin film transistor, a first electrode, a light-emitting functional layer and a second electrode on a surface of the base substrate facing the film layer and the fingerprint identification circuit.

15. A display device, comprising the display panel according to claim 12.

16. The display device according to claim 15, further comprising a motherboard, wherein the connection line is connected with the motherboard, and the motherboard is configured to receive a signal transmitted by the connection line to achieve fingerprint identification.

17. The display device according to claim 16, wherein the motherboard is connected with the connection line via a main control line.

18. The display panel according to claim 12, wherein the film layer comprises a plurality of sub-layers, and the connection line is located in one of the plurality of sub-layers.

19. The display panel according to claim 12, wherein the film layer comprises a plurality of sub-layers, and the connection line is located between two adjacent sub-layers of the plurality of sub-layers.

20. The display panel according to claim 12, wherein the film layer comprises a heat dissipation film.
